(19) United States
(12) Patent Application Publication
(10) Pub. No.: US 2021/0072349 A1
(43) Pub. Date: Mar. 11, 2021

(54) MONITORING AN FMCW RADAR SENSOR

(71) Applicant: Robert Bosch GmbH, Stuttgart (DE)

(72) Inventors: Marcel Mayer, Lonsee (DE); Michael Schoor, Stuttgart (DE)

(21) Appl. No.: 16/772,125

(22) PCT Filed: Jan. 31, 2019
(86) PCT No.: PCT/EP2019/052351

§ 371 Date: Jun. 11, 2020

(30) Foreign Application Priority Data
May 2, 2018 (DE) 10 2018 206 701.5

(51) Int. Cl. G01S 7/40

(52) U.S. Cl. CPC G01S 7/40; G01S 7/4017; G01S 7/4008

(57) ABSTRACT

A method for monitoring an FMCW radar sensor and an FMCW radar sensor, including multiple local oscillators. In the method, a first local oscillator signal of a first local oscillator of the local oscillators is mixed in a mixer with a second local oscillator signal of a second local oscillator of the local oscillators to form a baseband signal. The baseband signal is evaluated. A fault is detected due to a result of the evaluation. Methods for monitoring an FMCW radar sensor and an FMCW radar sensor including multiple high frequency components are described which each include a transceiver part for outputting a transmit signal to at least one antenna assigned to the high frequency component and for receiving a receive signal from at least one antenna assigned to the high frequency component.

### FIELD

The present invention relates to a method for monitoring an FMCW radar sensor including multiple local oscillators.

### BACKGROUND INFORMATION

Radar sensors are used in motor vehicles in an increasing scope to detect the traffic surroundings and supply pieces of information about distances, relative speeds, and directional angles of located objects to one or multiple assistance function(s), relieving the driver in driving the motor vehicle or entirely or partially replacing the human driver. With increasing autonomy of these assistance functions, increasingly higher requirements are placed not only on the performance capability, but also on the reliability of the radar sensors.

### SUMMARY

It is an object of the present invention to increase the reliability of the frequency generation of a radar sensor.

The object may be achieved according to an example embodiment of the present invention. In accordance with an example embodiment of the present invention, a method is provided for monitoring an FMCW radar sensor including multiple local oscillators. In the example method, a first local oscillator signal of a first local oscillator of the local oscillators being mixed in a mixer with a second local oscillator signal of a second local oscillator of the local oscillators to form a baseband signal, and the baseband signal being evaluated, a fault being detected based on a result of the evaluation.

By mixing the first local oscillator signal with the second local oscillator signal and evaluating the baseband signal, deviations from an expected frequency characteristic of the baseband signal may be detected in the baseband signal. The monitoring may thus be carried out as an internal function of the radar sensor during ongoing operation.

As a result of the use of local oscillator signals which are frequency-modulated in a ramp-shaped manner, a monitoring of the generation of the FMCW frequency ramps may take place. In this way, it is possible to monitor not only a local oscillator signal having a constant frequency, but it is also possible to monitor parameters of the FMCW frequency ramps, without external, complex measuring devices being necessary for this purpose. The evaluation in the baseband signal may furthermore take place with the aid of an analog-to-digital converter for the channels of the radar sensor which is already provided in the FMCW radar sensor.

The object may also be achieved by an example FMCW radar sensor in accordance with the present invention. The example FMCW radar sensor includes multiple local oscillators, the FMCW radar sensor being designed to carry out the method described here. For example, the FMCW radar sensor may be an FMCW radar sensor including multiple high frequency components, which each include a transceiver part and a local oscillator.

Advantageous embodiments and refinements of the present invention are described herein.

The example method is preferably a method for monitoring an FMCW radar sensor including multiple high frequency components, which each include a transceiver part for outputting a transmit signal to at least one antenna assigned to the high frequency component, and for receiving a receive signal from at least one antenna assigned to the high frequency component, a first high frequency component of the FMCW radar sensor including the first local oscillator, and a second high frequency component of the FMCW radar sensor including the second local oscillator, in the method the first local oscillator signal of the first local oscillator of the first high frequency component being transmitted to the second high frequency component and being mixed, in a mixer of the second high frequency component, with the second local oscillator signal of the second local oscillator of the second high frequency component to form the baseband signal.

The first local oscillator signal and the second local oscillator signal preferably have a frequency offset with respect to one another. A setpoint value of the frequency offset is preferably constant. For example, the first local oscillator signal and the second local oscillator signal may each be a local oscillator signal in the form of an FMCW frequency ramp, which have an identical setpoint value in their ramp slope. However, it is also possible to use first and second local oscillator signals having a constant frequency for certain evaluations.

For establishing a temporal relationship between starting points in time of the first and second local oscillator signals, a reference clock signal of the first and second high frequency sources of the FMCW radar sensor is preferably supplied, the first high frequency source encompassing the first local oscillator, and the second high frequency source encompassing the second local oscillator. For example, for establishing a temporal relationship between starting points in time of the first and second local oscillator signals, a reference clock signal may be supplied to reference clock signal inputs of the first and second high frequency components. The reference clock signal may be used, for example, to establish identical starting points in time of FMCW frequency ramps. In general, the reference clock signal may be used to establish a time basis for the activation of the first and second local oscillators. For example, the starting points in time of the first and second local oscillator signals may be synchronized.

In one exemplary embodiment, the first and second local oscillator signals may each be a local oscillator signal in the form of an FMCW frequency ramp, the FMCW frequency ramps having an identical setpoint value in their slope. During the evaluation of the baseband signal, a setpoint value of a frequency offset between the FMCW frequency ramps and a frequency shift corresponding to a signal propagation time of the transmission path is preferably taken into consideration. The setpoint value of a frequency offset between the FMCW frequency ramps is preferably not equal to zero.

The transmission of the first local oscillator signal from the first local oscillator to the mixer, or from the first high frequency component to the second high frequency component, may take place in a variety of ways. For example, the first local oscillator signal may be supplied to the mixer via a transmission path having a known signal propagation time. For example, the first local oscillator signal may be supplied from a signal output of the first high frequency component via a signal line to a signal input of the second high frequency component.

For example, the baseband signal may be evaluated taking the signal propagation time of the transmission path into consideration.

In one example, the FMCW radar sensor may be designed for normal operation, in which the first high frequency component operates as the master, and the second high frequency component operates as the slave, and a local oscillator signal of the first high frequency component is supplied from a synchronization signal output of the first high frequency component to a synchronization signal input of the second high frequency component for synchronizing the second high frequency component with the first high frequency component, the method being carried out during a measuring operation, and the first local oscillator signal being supplied from the synchronization signal output of the first high frequency component via a signal line to the synchronization signal input of the second high frequency component during the measuring operation. In another example, the first local oscillator signal may be supplied from a transmitter output of a transceiver part of the first high frequency component via a signal line to a receiver input of a transceiver part of the second high frequency component. In particular, when a radar sensor including multiple identical high frequency components, which each include a local oscillator, is used, the local oscillators, which are actually not necessary for a normal operation in a master/slave configuration in the high frequency components operated as slaves, may be used for monitoring the frequency generation of the local oscillator of the high frequency component operated as the master. The use of identical high frequency components additionally results in a more cost-effective implementation of powerful radar sensors.

In one further specific embodiment of the present invention, the first local oscillator signal is further processed into a transmit signal by a first transceiver part of the FMCW radar sensor, transmitted via at least one first antenna, and supplied to a second transceiver part of the FMCW radar sensor with the aid of cross-talk on at least one second antenna. For example, the first local oscillator signal is further processed into a transmit signal by a transceiver part of the first high frequency component, transmitted via at least one first antenna, and supplied to a transceiver part of the second high frequency component with the aid of cross-talk on at least one second antenna. The signal transmitted via the antenna may, for example, cross-talk on an antenna assigned to the second high frequency component in the sensor or at the radome of the sensor.

In one example, the first and second local oscillators are each controlled by a phase-locked loop of the particular first or second high frequency component, input signals of the phase-locked loops being synchronized with one another, and the evaluation of the baseband signal including: determining a noise level in a baseband range outside a peak of the baseband signal, and comparing the determined noise level to an expected noise level.

The example method according to the present invention may also be used for mutually monitoring the signal generation of the first local oscillator and of the second local oscillator, or for mutually monitoring the signal generation of the first high frequency component and of the second high frequency component. The example method according to the present invention may also be expanded to the use of more than two local oscillators of the FMCW radar sensor, whose local oscillator signals are separately evaluated in the baseband. The example method according to the present invention may, for example, be expanded to the use of more than two local oscillators of more than two high frequency components, whose local oscillator signals at at least one high frequency component are separately evaluated in the baseband.

For example, a third local oscillator signal may have a setpoint value of a frequency offset with respect to the second local oscillator signal, which differs from a setpoint value of a frequency offset which the first local oscillator signal has with respect to the second local oscillator signal. In one example, the first local oscillator signal of the first local oscillator of the first high frequency component of the FMCW radar sensor and a third local oscillator signal of a third local oscillator of a third high frequency component of the FMCW radar sensor may be transmitted to the second high frequency component of the FMCW radar sensor and mixed, in the mixer of the second high frequency component, with the second local oscillator signal of the second local oscillator of the second high frequency component to form the baseband signal, a frequency offset between the third and second local oscillator signals differing from a frequency offset between the first and second local oscillator signals.

Exemplary embodiments of the present invention are described in greater detail below based on the figures.

### BRIEF DESCRIPTION OF THE DRAWINGS

FIG. 1 shows a layout of a radar sensor including four high frequency components, which are connected to one another via an oscillator signal network.

FIG. 2 shows a frequency-time diagram of local oscillator signals and an amplitude spectrum of a baseband signal.

FIG. 3 shows a frequency-time diagram of local oscillator signals and an amplitude spectrum of a baseband signal according to one modified specific embodiment.

FIG. 4 shows an amplitude spectrum of a baseband signal to explain the evaluation of a noise level.

### DETAILED DESCRIPTION OF EXAMPLE EMBODIMENTS

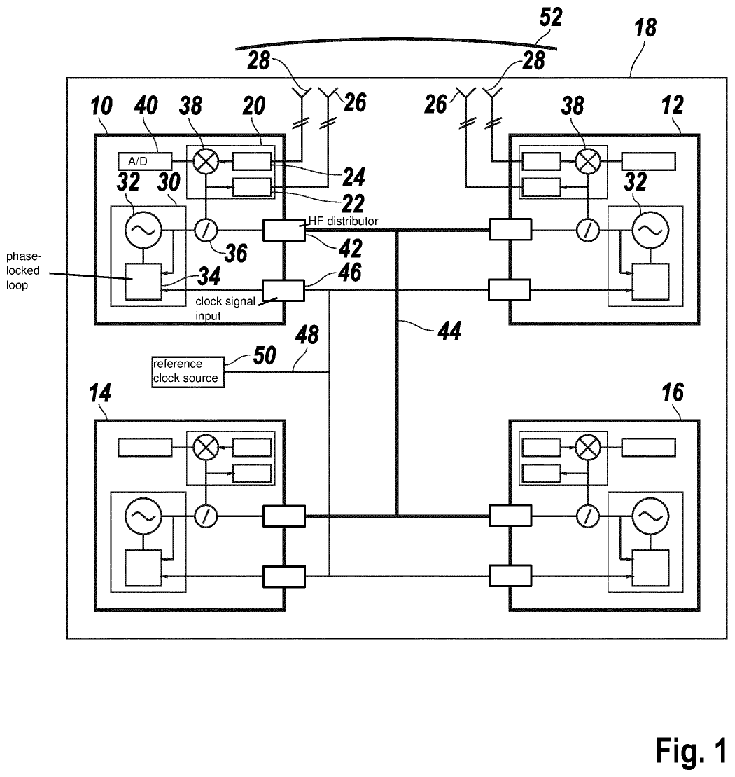

FIG. 1 shows four high frequency components 10, 12, 14, 16 of a radar sensor, which are situated on a shared substrate 18. The high frequency components are each an integrated circuit in the form of a monolithic microwave integrated circuit (MMIC) chip.

Each high frequency component includes a transceiver part 20, which encompasses at least one transmitter output 22 and one receiver input 24, which are connected to assigned antennas 26, 28 of the radar sensor. Multiple transmitting antennas 26 and/or multiple receiving antennas 28 may be assigned to each high frequency component. A transmitting antenna 26 and a receiving antenna 28 are shown by way of example. Transceiver part 20 may be used, among other things, to amplify the oscillator signal, which has a frequency in the range of 76 GHz, for example, and to divide it among the transmitting antennas. The receiving antennas may be identical to the transmitting antennas. Transceiver parts 20 may optionally also include circuits, with the aid of which the transmit signals supplied to the individual antennas are modified in their phase position and, if necessary, also in their frequency position, to achieve a suitable beamforming and a preferably good angular resolution of the radar system.

Each high frequency component furthermore includes a high frequency source 30, which encompasses a local oscillator 32 including a phase-locked loop 34 and is designed to generate a local oscillator signal, which may be supplied to transceiver unit 20 via a switching network 36. Phase-locked loop 34 includes a frequency divider. The local oscillator signal is mixed at a mixer 38 of transceiver part 20 with a receive signal to form a baseband signal and is supplied to an evaluation via an A/D converter 40 in a conventional manner. It is possible for multiple such receiver channels, including a respective mixer and A/D converter, to be provided.

Via switching network 36, the local oscillator signal may additionally be supplied to an HF distributor 42 operating as a synchronization signal output. The HF distributors of the high frequency components, which may operate as a synchronization signal output or a synchronization signal input, are connected to one another via an oscillator signal network 44.

Moreover, each high frequency component includes a reference clock signal input 46 for a reference clock signal, which is supplied via a reference clock signal line 48 from a reference clock source 50 and used to synchronize the frequency generation of high frequency sources 30 with one another.

Antennas 26, 28 of the radar sensor are situated behind a radome 52.

High frequency source 30 is designed to generate a frequency-modulated local oscillator signal in the form of an FMCW frequency ramp. Optionally, however, the frequency modulation may also take place inside each individual transceiver part 20.

Switching networks 36 are designed to configure the radar sensor for a master/slave configuration during normal operation. During normal operation using a master/slave configuration, the local oscillator signal of local oscillator 32 of first high frequency component 10 is supplied from HF distributor 42, operating as a synchronization signal output, via a signal line of oscillator signal network 44 to other high frequency components 12, 14, 16, operating as slaves. First high frequency component 10 is configured as the master. In each high frequency component configured as a slave, the local oscillator signal supplied from the outside via oscillator signal network 44 is supplied to transceiver part 20 via HF distributor 42, operating as the synchronization signal input, and switching network 36, and is used to generate the transmit signals for one or multiple assigned radar antenna(s) 26. In this way, the high frequency components operate synchronously, using the local oscillator signal of first high frequency component 10.

To carry out a monitoring of the frequency generation of high frequency source 30 during ongoing operation of the radar sensor, the radar sensor is intermittently switched into a measuring operation, which may also be referred to as monitoring measuring operation, between measuring cycles of the normal operation. The measuring operation differs from normal operation. A reconfiguration of the generation and distribution of the local oscillator signals takes place for the measuring operation. During the measuring operation, at least two of the high frequency components are operated as signal sources, and at least one of them is supplied the local oscillator signal of the other high frequency component via a transmission path having a defined signal propagation time, and is mixed with its own local oscillator signal and digitized in the A/D converter and supplied to a further evaluation. In this way, a frequency shift of the obtained baseband signal which results from the signal propagation time of the transmission path may be taken into consideration and, for example, be calculated therefrom. The consideration enables a particularly precise monitoring of the frequency of the generated local oscillator signals. This is described hereafter by way of example based on first and second high frequency components 10, 12.

Local oscillator 32 of first high frequency component 10 generates a local oscillator signal, which is supplied to second high frequency component 12 on a transmission path to be described in greater detail below. Local oscillator 32 of second high frequency component 12 generates its own local oscillator signal, simultaneously and synchronously with local oscillator 32 of first high frequency component 10. Both local oscillator signals are mixed in a mixer, for example a mixer 38 of transceiver part 20, to form a baseband signal and are supplied to A/D converter 40.

The two active signal sources 30 of first and second high frequency components 10, 12 are configured in such a way that the generated FMCW ramps have an identical starting point in time and an identical ramp slope, however the center frequency is slightly offset. A synchronization of the signal generation takes place via the reference clock signal, for example.

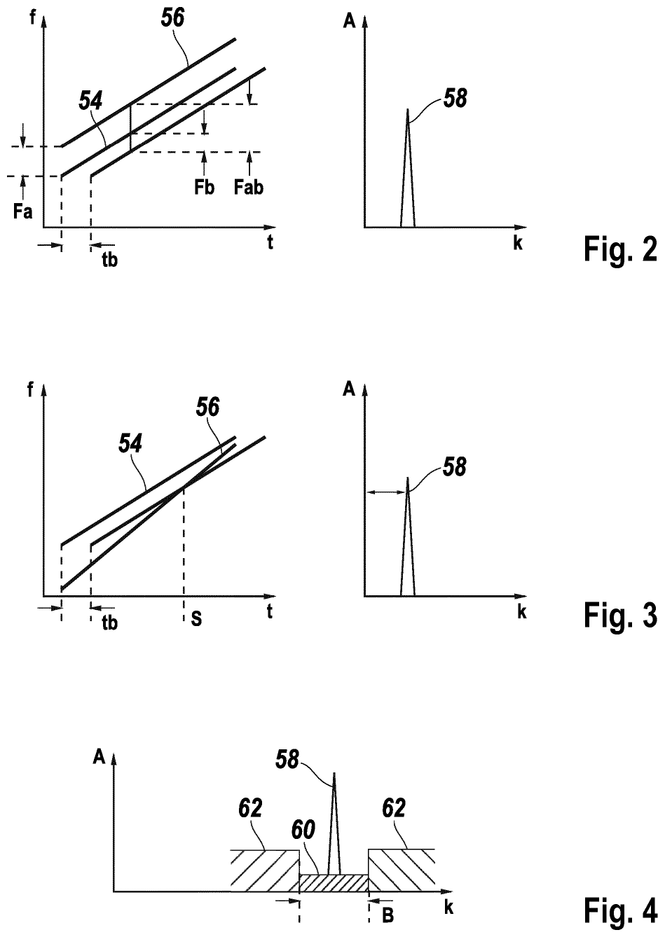

FIG. 2 schematically shows frequency ramp 54 of the local oscillator signal of the first high frequency component and frequency ramp 56 of the local oscillator of second high frequency component 12, which is shifted by a frequency offset Fa. The local oscillator signal of the first high frequency component is obtained at second high frequency component 12 with a time delay corresponding to a signal propagation time tb, which due to the ramp slope corresponds to a frequency shift Fb.

A resulting frequency shift Fab is thus present in the signals supplied to the mixer, which corresponds to the sum Fa+Fb, for example. In the amplitude spectrum of the baseband signal shown on the right side of FIG. 2, a peak is obtained at the resulting frequency shift Fab. This peak is stored in a corresponding bin of the spectrum. The spectrum is calculated in a conventional manner with the aid of a Fourier transform of the digitized baseband signal.

The shift Fa of the center frequency is selected within the bandwidth of the baseband. At a sampling rate of 10 MHz, for example, corresponding to a baseband width of 5 MHz, a frequency offset Fa of 2.5 MHz is selected, for example.

The transmission of the local oscillator signal from first high frequency component 10 to second high frequency component 12 may take place in a variety of ways.

For example, the local oscillator signal of the first high frequency component may be supplied via a signal output, for example HF distributor 42, and via a signal line, in particular, via oscillator signal network 44, to a signal input, such as HF distributor 42, of second high frequency component 12.

Oscillator signal network 44, via which the synchronization of the slaves with the master takes place during normal operation, is thus used as the signal line. Optionally, however, a separate signal line may be provided for supplying the local oscillator signal of one high frequency component to another high frequency component. For example, a transmitter output 22 of first high frequency component 10 may be connected to a receiver input 24 of second high frequency component 12 via an accordingly switched signal line. Optionally, however, it is also possible for signal inputs and signal outputs of the high frequency components which have a simple design to be provided, which, for example, may be designed for a lower signal power than transmitter outputs 22 or receiver inputs 24.

Optionally, the effect that a cross-talk of a signal transmitted via an antenna 26 on a receiving antenna 28 of another high frequency component takes place in the radar sensor or at radome 52 of the radar sensor may be utilized as a further option of the signal transmission. This transmission path between a first high frequency component and a second high frequency component also has a defined signal propagation time, which may be taken into consideration as a frequency shift Fb during the evaluation. When a transmission takes place with the aid of cross-talk, no dedicated signal lines are thus necessary for connecting first high frequency component 10 to second high frequency component 12.

Examples of the monitoring of the frequency generation are explained in greater detail hereafter.

A monitoring of the ramp center frequency of the local oscillator signal or of the frequency offset between two local oscillators may take place as follows. Since the expected frequency of the signal (peak 58) in the baseband signal in the example of FIG. 2 is known and corresponds to the configured or setpoint frequency offset Fa, combined with the expected frequency shift Fb, due to the propagation time of the cross-talk or of the signal transport between the high frequency components, the expected frequency may be compared to the measured, resulting frequency offset Fab. When a difference of the compared values exceeds a threshold value, the fault is detected. In particular, a faulty frequency offset is detected, and a faulty frequency of a frequency ramp is thus detected, for example a faulty ramp center frequency. The accuracy of the estimation of the measured baseband frequency depends on the duration of the signal to be evaluated, i.e., on the duration of a frequency ramp. Even in the case of a rapid ramp having a duration of 15 ps, for example, and a corresponding width of an

FFT bin of 20 kHz, a high estimation accuracy of, for example, considerably less than 1 kHz may be achieved due to the high signal strength. Deviations in the frequency generation between the two local oscillators of first and second high frequency components 10, 12 may thus be determined very precisely. It is even possible to monitor the generation of rapid ramps.

A monitoring of the ramp slope of a frequency ramp may thus take place as follows. The local oscillator signals according to the example from FIG. 2 may again be utilized. If the ramp slopes of the local oscillators of first and second high frequency components 10, 12 are different, a baseband signal which corresponds to a frequency chirp arises. The baseband signal has a frequency which changes over time. When a shift in the frequency position of peak 58 in the time curve of the local oscillator signals is detected, the fault is detected. In particular, a faulty ramp slope is then detected. A frequency chirp may be detected based on the obtained baseband signal and may be detected as a fault. For example, a parametric estimation method may be used for this purpose, or a chirplet transform, or it is possible to transform portions of the frequency ramps separately in spectra during the time curve, so that a time curve of a peak may be identified in the baseband signal.

An evaluation of the phase noise of high frequency source 30 may take place as follows. For this purpose, the two high frequency sources 30 of first high frequency component 10 and of second high frequency component 12 are synchronized with their respective phase-locked loop, PLL, 34 on a shared reference clock of a reference clock signal. The reference clock signal is supplied via reference clock signal line 48, for example. The local oscillator signal of first high frequency component 10 is transmitted to second high frequency component 12 and is again mixed, with the aid of a mixer 38, with the local oscillator signal of second high frequency component 12 to form the baseband. The above-described transmission paths may optionally be used as the transmission path. The noise obtained in the baseband signal is examined.

FIG. 4 schematically shows an amplitude spectrum of the baseband signal. Within the loop bandwidth of phase-locked loop 34, the phase noise of the individual local oscillator is dominated by the noise of the reference clock. Within the loop bandwidth around the local oscillator signal, the phase noise of local oscillators 32 of the high frequency components is thus highly correlated. Phase noise 60 within the loop bandwidth around the carrier signal (peak 58 in the frequency spectrum) is thus heavily suppressed in the baseband signal. The frequency of peak 58 in the frequency spectrum, in turn, corresponds to the frequency offset between the first and second local oscillator signals present at the mixer. The expected frequency offset, in turn, corresponds to an optional setpoint frequency offset between the two local oscillators, combined with the frequency shift resulting from the propagation time of the transmission path. The loop bandwidth may, for example, correspond to a frequency range of 300 kHz around the carrier signal. Outside the loop bandwidth, the phase noise of the individual local oscillator 32 is dominated by the noise behavior of the voltage-controlled oscillator 32. In the baseband signal, phase noise 62 is thus not correlated outside the loop bandwidth and is thus comparatively strong. The evaluation of the baseband signal may include, for example: determining a noise level in a band range outside a peak of the baseband signal; and comparing the determined noise level to an expected noise level. For example, within a bandwidth around a peak of the baseband signal, the bandwidth corresponding to the loop bandwidth of the phase-locked loops of the local oscillators, the noise level may be determined and compared to a corresponding, expected noise level. For example, outside a bandwidth around a peak of the baseband signal, the bandwidth corresponding to the loop bandwidth of the phase-locked loops of the local oscillators, the noise level may be determined and compared to a corresponding, expected noise level.

When an expected noise level is exceeded or exceeded by more than a threshold value, the fault is detected. In particular, a faulty phase-locked loop is then detected.

The evaluation of the baseband signal may include, for example:

determining a width B of a range having a lower noise level (in a band range outside a peak 58 of the baseband signal) within a surrounding range having a higher noise level; and

comparing the determined width B to an expected width, the expected width corresponding to the loop bandwidth of the phase-locked loops of the local oscillators.

When a difference of the compared values exceeds a threshold value, the fault is detected. In particular, a faulty phase-locked loop is then detected. In this way, it is possible to check the loop bandwidth. A deviation of the width of the low noise level from a width expected for the setpoint value of the loop bandwidth of the phase-locked loops may thus be detected, and be detected as a fault. The monitoring of the phase noise of a phase-locked loop of a local oscillator may usually only be determined during CW operation of a radar sensor, i.e., at a constant frequency, but not during the generation of an FMCW ramp. With the aid of the described method, a noise level of the phase noise may also be evaluated and monitored during the generation of an FMCW frequency ramp.

Based on FIG. 3, a modified specific embodiment of the present invention for the monitoring of the frequency offset and/or of the ramp slope is described. The example of FIG. 3 differs from the example of FIG. 2 in that different ramp slopes of FMCW frequency ramp 54, 56 are selected for the two local oscillators. The evaluation of the last frequency offset is then possible in the time range in which the point in time is determined at which the frequency ramps of the signals which are mixed together intersect. During the evaluation of the baseband signal, point in time S is then determined at which the ramp of the local oscillator of the second high frequency component intersects with the frequency ramp of the local oscillator of first high frequency component 10 which is obtained at the mixer of the second high frequency component, i.e., has the same frequency. In the frequency spectrum, this corresponds to a DC voltage pass through of the peak, i.e., the difference frequency of the signals is equal to zero. Based on a comparison of the measured point in time S to the expected point in time, taking time shift tb of the transmission path into consideration, it is thus possible to detect a ramp center frequency deviating from the setpoint value. This is detected as a fault. A deviation of a ramp slope from a setpoint value of the ramp slope also results in a time offset of the ramp intersection point and may thus be detected. When measurements are carried out consecutively with multiple frequency ramps having different ramp slopes, a deviation of the ramp slope may be distinguished from a deviation of the ramp center frequency.

In the specific embodiments of the present invention, a monitoring of the first high frequency component may be carried out by using the second high frequency component as the reference signal source. However, it is also possible to correspondingly provide a mutual monitoring of the high frequency components.

The described specific embodiments of the present invention make it possible to also monitor the frequency generation of a local oscillator with respect to the parameters which are difficult to determine with the aid of measuring instruments, such as phase noise, ramp center frequency and ramp slope. In particular, the monitoring during ongoing operation of the radar sensor is made possible.

Furthermore, it is also possible to simultaneously operate more than two high frequency components as signal sources during the measuring operation. For example, a monitoring in pairs may take place. However, it is also possible to operate multiple high frequency components simultaneously, whose signals are transmitted to an evaluating high frequency component and are mixed there with its own local oscillator signal. In this way, for example, a frequency offset of, e.g., 1 MHz may be selected between first high frequency component 10 and second high frequency component 12, which differs from a frequency offset of, e.g., 1.2 MHz between second high frequency component 12 and third high frequency component 14, and from a frequency offset between the first high frequency component and third high frequency component 14. For multiple high frequency components serving as the signal source, the respective mixed baseband signals are then obtained at the corresponding positions of the frequency offsets in the baseband of an evaluating high frequency component, and may be separately evaluated. For example, signals may then be received at 1 MHz and 2.2 MHz at the first high frequency component, signals of 1 MHz and 1.2 MHz may be received at the second high frequency component, and signals of 1.2 MHz and 2.2 MHz may be received at the third high frequency component.

Instead of separate high frequency components 10, 12, 14, 16 including respective local oscillators 32, it is also possible for high frequency components which each include multiple local oscillators 32, or a high frequency component including multiple local oscillators 32, to be provided. For example, two or more high frequency sources 30, respective mixers 36, transceiver parts 20, and A/D converters 40 may be integrated into a high frequency component. For example, instead of separate high frequency components 10, 12, a corresponding number of corresponding high frequency units may be integrated into a high frequency component, i.e., on a shared chip. Oscillator signal network 44 may be an internal network, for example.

1-10 (canceled)

11. A method for monitoring an FMCW radar sensor including multiple local oscillators, the method comprising the following steps:
mixing, in a mixer, a first local oscillator signal of a first local oscillator of the local oscillators with a second local oscillator signal of a second local oscillator of the local oscillators to form a baseband signal;
evaluating the baseband signal; and
detecting a fault based on a result of the evaluation.

12. The method as recited in claim 11, wherein the FMCW radar sensor includes multiple high frequency components which each include a transceiver part configured to output a transmit signal to at least one antenna assigned to the high frequency component, and configured to receive a receive signal from at least one antenna assigned to the high frequency component, a first high frequency component of the FMCW radar sensor including the first local oscillator, and a second high frequency component of the FMCW radar sensor including the second local oscillator, and wherein the first local oscillator signal of the first local oscillator of the first high frequency component is transmitted to the second high frequency component and being mixed, in the mixer, with the second local oscillator signal of the second local oscillator of the second high frequency component to form the baseband signal, the mixer being a mixer of the second high frequency component.

13. The method as recited in claim 11, wherein the first local oscillator signal is supplied to the mixer via a transmission path having a known signal propagation time, the baseband signal being evaluated taking the signal propagation time of the transmission path into consideration.

14. The method as recited in claim 13, wherein each of the first local oscillator signal and the second local oscillator signal is a local oscillator signal in the form of an FMCW frequency ramp, the FMCW frequency ramps having an identical setpoint value in their slope, and the evaluation of the baseband signal including:
comparing a frequency position of the baseband signal to an expected frequency position, the expected frequency position corresponding to a combination of a setpoint value of a frequency offset between the first local oscillator signal and second local oscillator signal and an expected frequency shift due to the signal propagation time of the transmission path, an absolute value of the expected frequency shift corresponding to a product from the setpoint value of the ramp slope and the signal propagation time of the transmission path.

15. The method as recited in claim 11, wherein each of the first local oscillator signal and the second local oscillator signal is a local oscillator signal in the form of an FMCW frequency ramp, the FMCW frequency ramps having an identical setpoint value in their slope, and the evaluation of the baseband signal including:
detecting a shift of a frequency position of the baseband signal in a time curve of the local oscillator signals.

16. The method as recited in claim 11, wherein each of the first local oscillator signal and the second local oscillator signal is a local oscillator signal in the form of an FMCW frequency ramp, the FMCW frequency ramps having different setpoint values in their slope, and during the evaluation of the baseband signal, a determination of a point in time being carried out at which a frequency of the baseband signal has a zero crossing.

17. The method as recited in claim 11, wherein each of the first local oscillator signal and the second local oscillators is controlled by a respective first phase-locked loop, input signals of the respective first phase-locked loops being synchronized with one another, and the evaluation of the baseband signal including:
determining a noise level in a baseband range outside a peak of the baseband signal; and
comparing the determined noise level to an expected noise level.

18. The method as recited in claim 11, wherein the first local oscillator signal is further processed by a first transceiver part of the FMCW radar sensor into a transmit signal, transmitted via at least one first antenna, and supplied to a second transceiver part of the FMCW radar sensor using cross-talk on at least one second antenna.

19. The method as recited in claim 11, wherein the first local oscillator signal of the first local oscillator of the FMCW radar sensor and a third local oscillator signal of a third local oscillator of the FMCW radar sensor are mixed in the mixer with the second local oscillator signal of the second local oscillator to form the baseband signal, a frequency offset between the third local oscillator signal and the second local oscillator signal differing from a frequency offset between the first local oscillator signal and the second local oscillator signal.

20. An FMCW radar sensor, comprising:
multiple local oscillators;
wherein the FMCW radar sensor is configured to:
mix, in a mixer, a first local oscillator signal of a first local oscillator of the local oscillators with a second local oscillator signal of a second local oscillator of the local oscillators to form a baseband signal;
evaluate the baseband signal; and
detect a fault based on a result of the evaluation.
